(19) United States
(12) Patent Application Publication
(10) Pub. No.: US 2013/0100610 A1
(43) Pub. Date: Apr. 25, 2013

(54) AIR DUCT ARRANGEMENT FOR COOLING A GROUP OF AT LEAST TWO HEAT PRODUCING MODULES

(71) Applicants: Gary Schneider, Saint Charles, IL (US); Bryan Kranyik, Loves Park, IL (US); Michael Feller, Machesney Park, IL (US)

(72) Inventors: Gary Schneider, Saint Charles, IL (US); Bryan Kranyik, Loves Park, IL (US); Michael Feller, Machesney Park, IL (US)

(73) Assignee: Danfoss A/S, Nordborg (DK)

(21) Appl. No.: 13/276,692

(22) Filed: Oct. 19, 2011

(51) Int. Cl. H05K 7/20

(52) U.S. Cl. 361/690

(57) ABSTRACT

An air duct arrangement for cooling a group (1) of at least two heat producing modules is provided, said modules (2, 3) being arranged one after the other in the direction of an air flow through said group (1), said air duct arrangement comprising an air path (5, 6) for each module (2, 3). The cooling of modules of a group of modules with cooling air should be enabled with only small space requirements. To this end said air paths (5, 6) are arranged in parallel along a lengthwise direction from a first side of said group (1) to a second side of said group (1), said second side being opposite to the first side, said air path (5, 6) changing their order in a direction perpendicular to said lengthwise direction in a region (13) between said two modules (2, 3).

### FIELD OF THE INVENTION

The present invention relates to an air duct arrangement for cooling a group of at least two heat producing modules, said modules being arranged one after the other in the direction of an air flow through said group, said air duct arrangement comprising an air path for each module.

### BACKGROUND OF THE INVENTION

Such an air duct arrangement is known from U.S. Pat. No. 5,136,464. The modules are arranged one above the other. The cooling air for the lower module is guided from the bottom of the lower module to the top of the lower module. A confluence preventing section being V-shaped is arranged on the top of the lower module guiding the cooling air having an elevated temperature to two opposing sides of the group of modules. Cooling air for the upper module is drawn from the other pair of opposing sides of the group to pass from the lower side of the upper module to the upper side of the upper module. The confluence preventing section prevents mixing of the air stream from the lower module with the air stream of cooler air supplied to the upper module.

U.S. Pat. No. 7,140,193 B2 discloses a rack-mounted equipment blowing cooling air from the front side of the rack-mounted equipment to the back side. The air to the front side is supplied via a channel arranged at the front side. The air to this channel is supplied with the help of a plurality of fans.

When two or more heat producing modules are arranged one after the other in the direction of an air flow through said group only the first module can be cooled with fresh cooling air having a sufficient low temperature to achieve cooling. However, the next and the following module receive cooling air having already an elevated temperature so that the cooling effect is reduced. As shown in U.S. Pat. No. 5,136,464 the cooling effect can be made almost the same for two modules by separating the air flows through the two modules. However, the prior art solution requires an air access to the group of modules from all sides, i.e. not only from the front or back side, but also from the remaining other two sides.

### SUMMARY OF THE INVENTION

The task underlying the invention is to enable cooling modules of a group of modules with cooling air with only small space requirements.

This task is solved in an air duct arrangement of the kind mentioned above in that said air path are arranged in parallel along a lengthwise direction from a first side of said group to a second side of said group, said second side being opposite to said first side, said air path changing their order in a direction perpendicular to said lengthwise direction in a region between said two modules.

In order to facilitate the further explanation an example of a group of modules is used having two modules, said modules being arranged one above the other. However, the invention is not limited to such an example. The air flow can be produced by air flow generating means, like a fan, and in this case the modules can be arranged one after the other in any desired direction. Furthermore, there can be more than only two modules.

With the solution mentioned above it is possible to supply fresh cooling air to each module. The lower module is cooled by cooling air entering the lower side of the lower module or at least an air path cooling said lower module. In a direction from the front to the back of the lower module this air path is the first air path. The cooling air for the upper module is guided through an air path on the back side of the lower module, e.g. outside the lower module. In the direction from the front to the back side of the lower module this is the second air path. In this way the cooling air in the second air path is not influenced by heat generated by the lower module. In a region between the lower module and the upper module the two air paths change their order in the direction from the front to the back side of the modules. After the change of order the air path guiding the air for cooling the upper module is the first air path in the direction from the front to the back side of an upper module and the air path guiding the cooling air of the lower module is the second air path in the direction from the front to the back side of the upper module. This cooling air has already an elevated temperature. However, this is no problem since the elevated temperature of the cooling air of the lower module does not influence the heat removal in the upper module.

Preferably each air path runs partly through a module and partly on a side of another module, said side being the same for all modules. In the example mentioned above the air paths run in one section through the associate modules and in another section on the back side of the other modules. The other three sides of the modules are free accessible for other purposes.

In a preferred embodiment a changeover section is arranged in the region between said two modules. The changeover section can be designed to throttle the air flow through the air path not more than unavoidable and hence the cooling effect of the cooling air flowing through the air path remains almost unchanged.

Preferably said changeover section comprises a separating wall separating adjacent air paths from each other. This separating wall is formed so that the change of order can be achieved.

In this case it is preferred that said separating wall has a twisted form. The separating wall can be formed by a sheet metal or any other sheet like material in which one end is twisted relative to the other end in lengthwise direction by 180°. This is a simple way to change the order of the air paths in a direction perpendicular to the lengthwise direction of the air paths without creating turbulences by sharp edges or the like.

Preferably said separating wall divides said air duct arrangement in two halves parallel to said lengthwise direction. The separating wall can run through the whole length of the air duct arrangement. However, in a preferred embodiment it runs only through the changeover section and in the remaining part of the air duct arrangement the two air paths are separated by the back side of the respective modules.

### BRIEF DESCRIPTION OF THE DRAWINGS

A preferred embodiment of the invention will now be described in more detail with reference to the drawing, wherein:

FIG. 1 is a schematic side view of a group of two modules,

FIG. 2 is a front view of said group and

FIG. 3 shows sections of the group shown in FIG. 2.

### DETAILED DESCRIPTION OF THE PREFERRED EMBODIMENTS

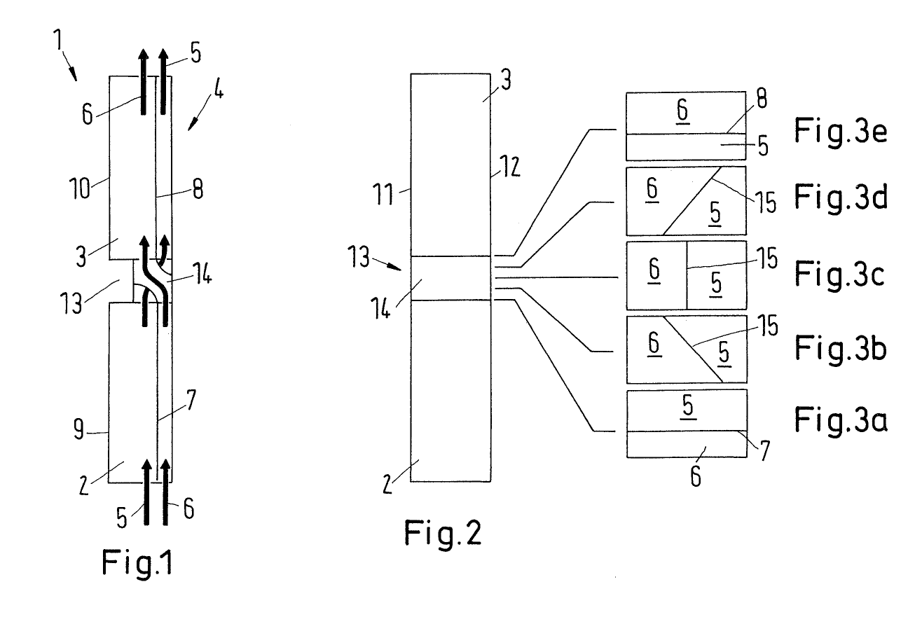

FIG. 1 schematically shows a group 1 of two modules 2, 3. Both modules 2, 3 produce heat. Such modules can be for example drives for electrical machines. The heat is unavoidably generated by losses of electrical energy.

In order to remove said heat and to keep the temperature of the modules 2, 3 below a predetermined level, a heat duct arrangement 4 is provided. This heat duct arrangement 4 comprises a first air path 5 (symbolized by arrows) for the first module 2 and a second air path 6 (symbolized by arrows as well) for the second module 3. These air paths 5, 6 are arranged in parallel in a direction from the lower side of said group 1 to the upper side of said group 1. The orientation of the modules 2, 3 in space is not limited to a vertical orientation. Therefore, the terms “lower” and “upper” are used in order to facilitate the explanation. The stack of modules 2, 3 in the group 1 can have any desired orientation.

The air paths 5, 6 run partly through the modules 2, 3 associated to each air path 5, 6, and partly on the back side 7 of the module 2 or the back side 8 of the module 3, respectively.

As can be seen in FIG. 1 the air paths 5, 6 have an order in a direction from a front side 9 of the lower module 2 to the back side 7 of the lower module 2. In the region of the lower module 2 the air path 5 is the first air path and the air path 6 is the second air path.

In the region of the upper module 3 the order has changed. In the region of the upper module 3 the air path 6 is the first air path in a direction from the front side 10 of the upper module 3 to the back side 8 of the upper module 3 and the air path 5 is the second air path.

In this way it is possible to guide the air in the first air path 5 through the lower module and than at the back side 8 of the upper module 3. The second air path 6 is guided on the back side 7 of the lower module 2 and then through the upper module 3. In this way the front sides 9, 10 of the modules 2, 3 and the lateral faces 11, 12 (FIG. 2) can be kept free. These sides are accessible for other purposes.

In order to enable the change of order of the two air paths 5, 6, in an intermediate region 13 between the two modules 2, 3 a changeover section 14 is arranged.

FIG. 3 shows different cross sections of the changeover section 14, these sections being taken on positions indicated by the five lines connecting the FIGS. 3a, 3b, 3c, 3d and 3e with FIG. 2.

FIG. 3a schematically shows the sections of the air paths 5, 6 at the upper end of the lower module 2. In this embodiment the air path 5 has a somewhat larger section than the air path 6. Electric components are arranged in the air path 5 which have to be cooled. However, the sections of two air paths 5, 6 may be equal or the section of air path 6 may be larger than that of air path 5.

FIGS. 3b to 3d show sections of the changeover section 14 showing a separating wall 15 dividing said air duct arrangement 4 in the region of the changeover section 14 in two halves parallel to said lengthwise direction, these two halves having in this embodiment the same cross section area. However, the cross section areas can be different.

The separating wall 15 is twisted. It starts at the back side 7 of the lower module 2 with it's lower end and ends at the back side 8 of the upper module 3 with it's upper end. The separating wall 15 is twisted between the two modules 2, 3, i.e. the upper end of the separating wall 15 is rotated relative to the lower end of the separating wall 15 by 180°.

In this way it is possible to guide the cooling air for the upper module 3 through the air path 6 outside of the lower module 2 and to guide the cooling air from the lower module 2 outside the upper module 3 without needing more than just the back side 7, 8 of the two modules 2, 3. No additional space is necessary. The total width of the air duct arrangement 1 is not wider than the total width of the two modules 2, 3 (as seen in the front view of FIG. 2). Air flow remains “bottom” to “top” of the group 1, i.e. there is a well defined entrance of cooling air at the bottom and a well defined exit of cooling air at the top of the group 1.

While the present invention has been illustrated and described with respect to a particular embodiment thereof, it should be appreciated by those of ordinary skill in the art that various modifications to this invention may be made without departing from the spirit and scope of the present invention.

What is claimed is:

1. An air duct arrangement for cooling a group of at least two heat producing modules, said modules being arranged one after the other in the direction of an air flow through said group, said air duct arrangement comprising an air path for each module, wherein said air paths are arranged in parallel along a lengthwise direction from a first side of said group to a second side of said group, said second side being opposite to the first side, said air paths changing their order in a direction perpendicular to said lengthwise direction in a region between said at least two modules.

2. The air duct arrangement according to claim 1, wherein each air path runs partly through a module and partly on a side of another module, said side being the same for all modules.

3. The air duct arrangement according to claim 1, wherein a changeover section is arranged in the region between said two modules.

4. The air duct arrangement according to claim 3, wherein said changeover section comprises a separating wall separating adjacent air paths from each other.

5. The air duct arrangement according to claim 4, wherein said separating wall has a twisted form.

6. The air duct arrangement according to claim 4, wherein said separating wall divides said air duct arrangement in two halves parallel to said lengthwise direction.

7. The air duct arrangement according to claim 2, wherein a changeover section is arranged in the region between said two modules.

8. The air duct arrangement according to claim 5, wherein said separating wall divides said air duct arrangement in two halves parallel to said lengthwise direction.
